(19) United States
(12) Patent Application Publication
(10) Pub. No.: US 2026/0198210 A1
(43) Pub. Date: Jul. 9, 2026

(54) Display Module And Electronic Device Including The Same

(71) Applicant: Samsung Display Co., Ltd., Yongin-si (KR)

(72) Inventors: Dong Gyu Baeck, Yongin-si (KR); Sujin Kim, Yongin-si (KR)

(73) Assignee: Samsung Display Co., Ltd., Yongin-si (KR)

(21) Appl. No.: 19/405,709

(22) Filed: Dec. 2, 2025

(30) Foreign Application Priority Data
Jan. 3, 2025 (KR) 10-2025-0001034

(51) Int. Cl. H10K 59/80; B82Y 20/00; C08G 71/02; C08G 73/06; C08K 3/013; C09K 11/02; H10K 59/38

(52) U.S. Cl. CPC H10K 59/877; C08G 71/02; C08G 73/06; C08K 3/013; C09K 11/02; H10K 59/38; B82Y 20/00

(57) ABSTRACT

A display module including a display layer providing source light, and a light control layer disposed on the display layer and including a plurality of light control portions, which are separated from one another, wherein each of the plurality of light control portions includes a base resin portion, the base resin portion includes a polymer derived from a resin composition containing an expanding monomer.

### CROSS-REFERENCE TO RELATED APPLICATIONS

This U.S. non-provisional patent application claims priority under 35 U.S.C. § 119 to Korean Patent Application No. 10-2025-0001034, filed on Jan. 3, 2025, the entire contents of which are hereby incorporated by reference.

### TECHNICAL FIELD

The present disclosure herein relates to a display module and an electronic device including the same, and more particularly, to a display device including a light control layer.

### BACKGROUND

Display devices include a transmissive display device that selectively transmits source light generated from a light source, and a light emitting display device that generates source light from a display device itself. The display devices may include different types of light control portions according to pixels to generate color images. The light control portions may transmit only a portion of the wavelength range of source light or convert the color of source light. Some light control portions may change the properties of light without converting the color of source light.

In the display devices, quantum dot materials are used in the light control portions, and for the purpose of enhancing the display quality of the display devices, there is a need for developing technology that allows for an increase in light conversion efficiency or light transmission efficiency in the light control portions.

### SUMMARY

The present disclosure provides a display device exhibiting improved display quality by increasing front transmittance of source light, and an electronic device including the same.

An aspect of the disclosure provides a display module including a display layer providing source light, and a light control layer disposed on the display layer and including a plurality of light control portions, which are separated from one another, wherein each of the plurality of light control portions includes a base resin portion, the base resin portion includes a polymer derived from a resin composition containing a first monomer, and the first monomer includes an expanding monomer.

In an aspect, the first monomer may include a carbonate-based compound or a benzoxazine-based compound.

In an aspect, the first monomer may include a compound represented by any one of Compound Group 1 below.

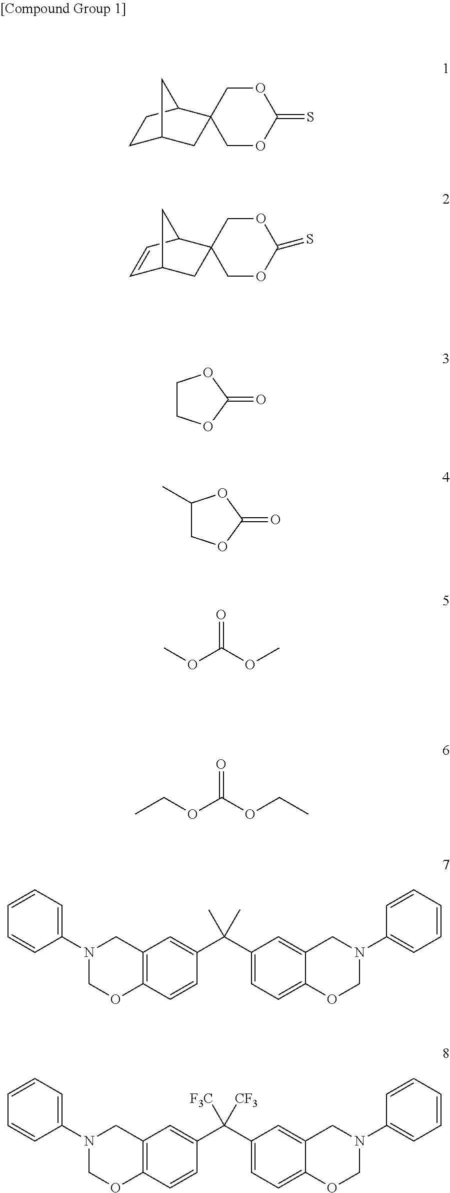

In an aspect, with respect to 100 parts by weight of the resin composition, the first monomer may range from about 30 parts by weight to about 70 parts by weight.

In an aspect, the resin composition may further include a second monomer different from the first monomer, and the second monomer may include hexamethylenediamine.

In an aspect, with respect to 100 parts by weight of the resin composition, the first monomer may range from about 30 parts by weight to about 70 parts by weight, and the second monomer may range from about 30 parts by weight to about 80 parts by weight.

In an aspect, at least some of the plurality of light control portions may further include quantum dots dispersed in the base resin portion and converting a wavelength of the source light.

In an aspect, each of the plurality of light control portions may further include scatterers dispersed in the base resin portion.

In an aspect, the scatterers may include at least one of TiO₂, SiO₂, BaSO₄, BaO, ZnS, ZnO, Al₂O₃, CaCO₃, or hollow silica.

In an aspect, the light control layer may further include a division pattern in which an opening exposing at least a portion of an upper surface of the display layer is defined, and the plurality of light control portions may be disposed in the opening and separated from one another by the division pattern.

In an aspect, the upper surface of each of the plurality of light control portions may have a convex shape in a direction away from the display layer.

In an aspect, a first height of the division pattern may be smaller than a second height of each of the plurality of light control portions.

In an aspect, each of the plurality of light control portions may include a flat portion disposed on the display layer, and a convex portion disposed on the flat portion.

In an aspect, a third height of the flat portion may be smaller than the first height of the division pattern.

In an aspect, the convex portion may have a fourth height of about 1 μm to about 3 μm.

In an aspect, the display module may be separated into a first pixel region emitting red light, a second pixel region emitting green light, and a third pixel region emitting blue light, when viewed on a plane, and the plurality of light control portions may include a first light control portion corresponding to the first pixel region, a second light control portion corresponding to the second pixel region, and a third light control portion corresponding to the third pixel region.

In an aspect, the display module may further include a color filter layer disposed on the light control layer, and the color filter layer may include a first color filter disposed corresponding to the first pixel region and transmitting the red light, a second color filter disposed corresponding to the second pixel region and transmitting the green light, and a third color filter disposed corresponding to the third pixel region and transmitting the blue light.

In an aspect, the display module may further include a low refractive layer disposed between the light control layer and the color filter layer.

In an aspect of the disclosure, a display module includes a display layer providing source light, and a light control layer disposed on the display layer, wherein the light control layer includes a division pattern in which an opening exposing at least a portion of an upper surface of the display layer is defined, and a plurality of light control portions which are disposed in the opening and are separated from one another by the division pattern, at least some of the plurality of light control portions include quantum dots converting a wavelength of the source light, each of the plurality of light control portions includes a flat portion disposed on the display layer, and a convex portion disposed on the flat portion, and the convex portion has a height of about 1 μm to about 3 μm.

In an aspect of the disclosure, an electronic device capable of providing an image includes a window, an outer case coupled to the window to accommodate a display module, and the display module disposed between the window and the outer case, wherein the display module includes a display layer providing source light, and a light control layer disposed on the display layer and including a plurality of light control portions, which are separated from one another, each of the plurality of light control portions includes a base resin portion, the base resin portion includes a polymer derived from a resin composition containing a first monomer, and the first monomer includes an expanding monomer.

### BRIEF DESCRIPTION OF THE FIGURES

The above and other aspects and features of the present disclosure will become more apparent by reading the following detailed description of non-limiting aspects and with reference to the accompanying drawings:

FIG. 1 is a block diagram of an electronic device according to an aspect;

FIG. 2 shows isometric views of electronic devices according to various aspects;

FIG. 3A is a combined perspective view of an electronic device according to an aspect;

FIG. 3B is an exploded perspective view of an electronic device according to an aspect;

FIG. 4 is a cross-sectional view showing a display module of an aspect;

FIG. 5 is a plan view of a display panel according to an aspect;

FIG. 6 is a plan view enlarging a portion of a display region in a display module according to an aspect;

FIG. 7 is a cross-sectional view showing a portion of a display module according to an aspect;

FIG. 8 is a cross-sectional view enlarging a portion of a display module according to an aspect;

FIG. 9A is a cross-sectional view showing a portion of a display module according to the Comparative Example; and

FIG. 9B is a cross-sectional view enlarging a portion of a light control layer according to the Comparative Example.

### DETAILED DESCRIPTION

The present disclosure may be modified in many alternate forms, and thus specific aspects will be exemplified in the drawings and described in detail. It should be understood, however, that it is not intended to limit the present disclosure to the particular forms disclosed, but rather, is intended to cover all modifications, equivalents, and alternatives falling within the spirit and scope of the present disclosure.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. The term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the disclosure. Similarly, a second element, component, region, layer or section could be termed a first element, component, region, layer or section. The singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

As used herein, the term “Group” refers to a group in the IUPAC periodic table.

As used herein, “Group II” may include Group IIA elements and Group IIB elements. For example, the Group II elements may be magnesium (Mg) or zinc (Zn), but are not limited thereto.

As used herein, “Group III” may include Group IIIA elements and Group IIIB elements. For example, the Group III elements may be aluminum (Al), indium (In), gallium (Ga), or titanium (Ti), but are not limited thereto.

As used herein, “Group V” may include Group VA elements and Group VB elements. For example, the Group V elements may be phosphorus (P), arsenic (As), or antimony (Sb), but are not limited thereto.

As used herein, “Group VI” may include Group VIA elements and Group VIB elements. For example, the Group VI elements may be oxygen (O), sulfur(S), selenium (Se) or tellurium (Te), but are not limited thereto.

Unless otherwise defined, all terms (including technical and scientific terms) used herein have the same meaning as commonly understood by one of ordinary skill in the art to which the present disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display module according to an aspect of the disclosure and an electronic device of an aspect will be described with reference to the accompanying drawings.

A display device according to an aspect may be applied to various electronic devices. The electronic device according to an aspect may include the display module described above, and may further include a module or device having additional functions in addition to the display module.

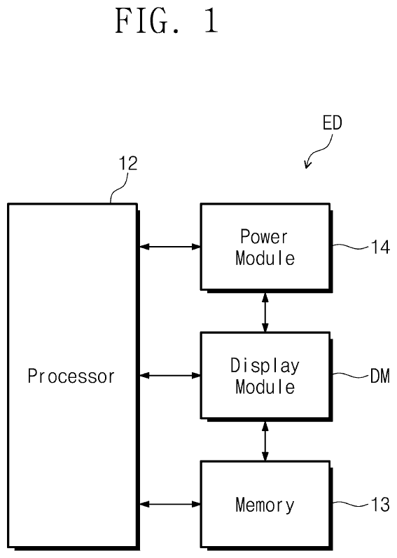

FIG. 1 is a block diagram of an electronic device according to an aspect. Referring to FIG. 1, an electronic device ED according to an aspect may include a display module DM, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module DM. When the processor 12 executes an application stored in the memory 13, image data signals and/or input control signals are transmitted to the display module DM, and the display module DM may process the received signal and output image information through a display screen.

The power module 14 may include a power supply module such as a power adapter or a battery device, and a power conversion module that converts power supplied by the power supply module to generate power required for the operation of the electronic device ED.

At least one of the components of the electronic device ED described above may be included in the display device according to the above-described aspects. In addition, some of the individual modules functionally included in one module may be included in the display device, and others may be separately provided from the display device. For example, the display device may include a display module DM, and the processor 12, the memory 13, and the power module 14 may be provided in the form of other devices within the electronic device ED, rather than the display device.

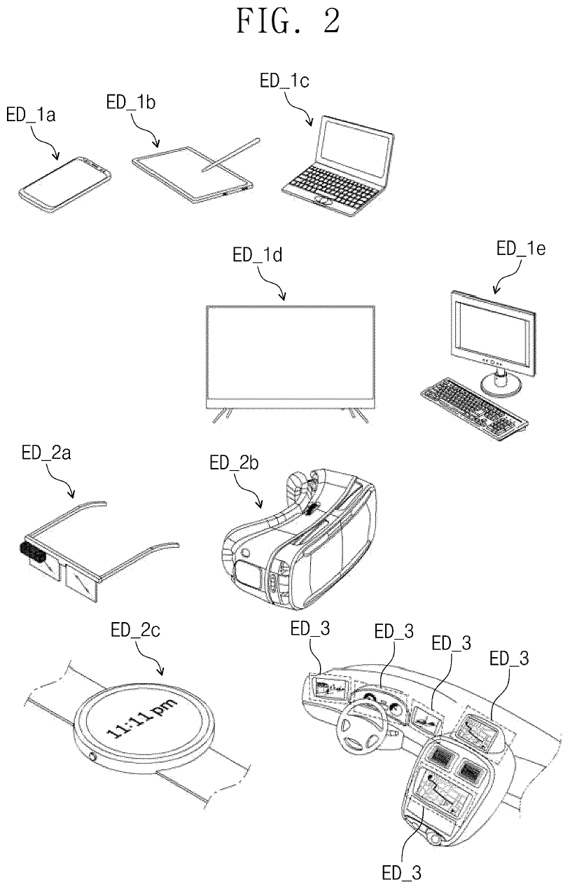

FIG. 2 shows perspective views of electronic devices according to various aspects.

Referring to FIG. 2, various electronic devices to which the display device according to aspects is applied may include an electronic device for displaying images, such as a smart phone ED_1a, a tablet PC ED_1b, a laptop ED_1c, a TV ED_1d, and a desk monitor ED_1e, a wearable electronic device including a display module such as a smart glasses ED_2a, a head mounted display ED_2b, and a smart watch ED_2c, and a vehicle electronic device ED_3 including a display module such as a center information display (CID) and a room mirror display disposed on an instrument panel, a center fascia, or a dashboard of a vehicle. In addition, these devices are merely provided as aspects, and other electronic devices may be employed.

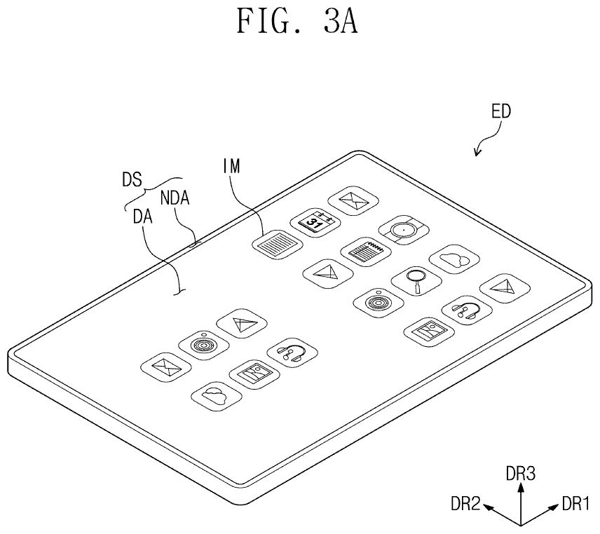

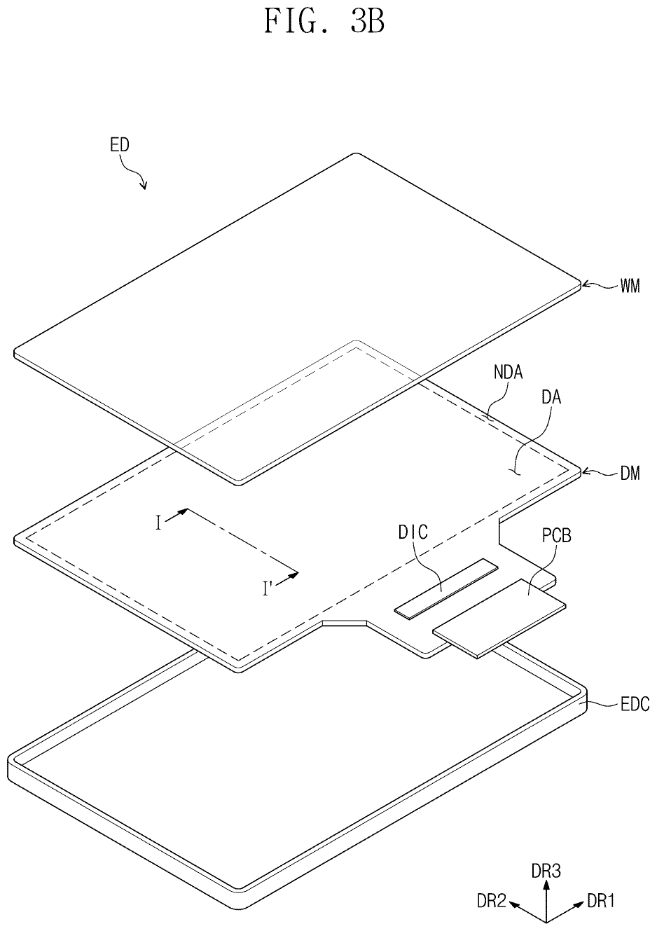

FIG. 3A is a combined perspective view of an electronic device according to an aspect. FIG. 3B is an exploded perspective view of an electronic device according to an aspect. FIGS. 3A and 3B are examples of any one of the image display electronic device, such as the smart phone ED_1a, the tablet PC ED_1b, the laptop ED_1c, the TV ED_1d, and the desk monitor ED_1e illustrated in FIG. 2; the wearable electronic device including a display module such as the smart glasses ED_2a, the head mounted display ED_2b, and the smart watch ED_2c; and the vehicle electronic device ED_3 including a display module such as a center information display (CID) and a room mirror display disposed on an instrument panel, a center fascia, or a dashboard of a vehicle, but are not limited to the illustrated forms.

The electronic device ED may display an image IM and sense external inputs. The electronic device ED may display the image IM towards a third direction DR3 on a display surface DS parallel to each of a first direction DR1 and a second direction DR2. The display surface DS on which the image IM is displayed may correspond to a front surface of the electronic device ED and also may correspond to a front surface FS of a window WM. As used herein, the phrase “a region/portion corresponds to a region/portion” indicates that they overlap and are not limited to the same area. Hereinafter, like reference numerals will be given for the display surface and the front surface of the electronic device ED, and the front surface of the window WM. The image IM may include still images as well as dynamic images. FIG. 3A shows a plurality of icons as an example of the image IM.

In the present aspect, a front surface (or an upper surface) and a rear surface (or a lower surface) of respective members are defined with respect to a direction in which the image IM is displayed. The front and rear surfaces may oppose each other in the third direction DR3 and a normal direction of each of the front and rear surfaces may be parallel to the third direction DR3. The distance between the front surface and the rear surface in the third direction DR3 may correspond to a thickness in the third direction DR3 of the electronic device ED. Meanwhile, directions indicated by the first to third directions DR1, DR3, and DR3 are relative concepts, and may thus be changed to other directions. Hereinafter, first to third directions correspond to directions indicated by the first to third directions DR1, DR2, and DR3, respectively, and are given the same reference numerals. In addition, herein, “on a plane” may refer to when viewed on a plane defined by the first direction DR1 and the second direction DR2.

In an aspect of the disclosure, the electronic device ED having a planar front surface DS is shown, but the aspect of the inventive concept is not limited thereto. The electronic device ED may include a curved display surface or a three-dimensional display surface. The three-dimensional display surface may include a plurality of display regions indicating different directions.

The electronic device ED according to an aspect may sense user inputs applied from the outside. For example, the user inputs include various types of external inputs such as a portion of the user's body, light, heat, or pressure. The user inputs may be provided in various forms, and the electronic device ED may sense the user inputs applied to the side or back of the electronic device ED depending on a structure of the electronic device ED. The aspects of this disclosure are not limited to any one user input.

As shown in FIG. 3B, the electronic device ED may include a window WM, a display module DM, and an outer case EDC. The window WM and the outer case EDC are combined to form the exterior of the electronic device ED. The outer case EDC, the display module DM, and the window WM may be sequentially stacked along the third direction DR3.

The window WM may include an optically transparent material. The window WM may include an insulating panel. For example, the window WM may be composed of glass, plastic, or a combination thereof.

The front surface FS of the window WM, as described above, defines a front surface of the electronic device ED.

The window WM may include a bezel region and a transmission region. The transmission region may be an optically transparent region. For example, the transmission region may be a region having a visible light transmittance of about 90% or greater.

The bezel region may be a region having a relatively lower light transmittance than the transmission region. The bezel region defines the shape of the transmission region. The bezel region may be adjacent to the transmission region and may surround the transmission region. The bezel region may have a predetermined color. The bezel region may overlap a non-display region NDA of the display module DM. The bezel region may cover the non-display region NDA of the display module DM and may block the non-display region NDA from being viewed from the outside. However, the bezel region may be optionally omitted.

The display module DM includes a display region DA and a non-display region NDA. The display region DA may be a region that provides an image IM, and the non-display region NDA may be a region in which driving circuits or driving lines are disposed. In the display region DA, light emitting elements of each of a plurality of pixels may be disposed. The non-display region NDA may be adjacent to the display region DA. The non-display region NDA may surround the display region DA. The display module DM may include a driving chip DIC disposed on the non-display region NDA. The display module DM may further include a printed circuit board PCB coupled to the non-display region NDA. The printed circuit board PCB may be electrically connected to pads disposed on the non-display region NDA through an anisotropic conductive adhesive layer.

The driving chip DIC may include driving elements, for example, a data driving circuit, for driving pixels of the display module DM. FIG. 3B shows a structure in which the driving chip DIC is mounted on the display module DM, but the aspects of this disclosure are not limited thereto. For example, the driving chip DIC may be mounted on the printed circuit board PCB.

The outer case EDC may accommodate the display module DM and may be coupled to the window WM. The outer case EDC may protect components accommodated in the outer case EDC, such as the display module DM.

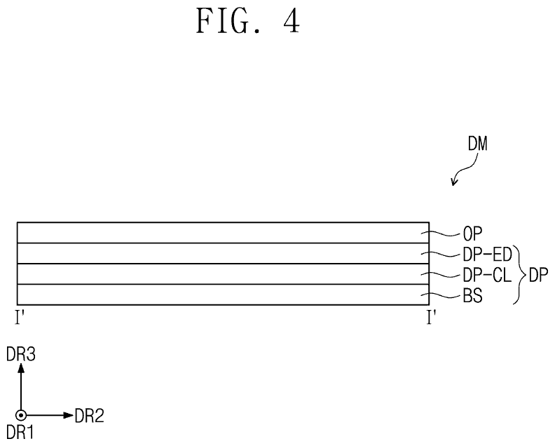

FIG. 4 is a cross-sectional view showing a display module of an aspect. FIG. 4 is a cross-sectional view showing a portion corresponding to line I-I′ of FIG. 3B.

Referring to FIG. 4, the display module DM of an aspect may include a display panel DP and a light control panel OP disposed on the display panel DP. The display panel DP may include a base layer BS, a circuit layer DP-CL, and a display layer DP-ED, which are sequentially stacked in a direction of a third directional axis DR3. The light control panel OP may be disposed on the display layer DP-ED. In the display module DM of an aspect, the light control panel OP may be directly disposed on the display layer DP-ED.

Herein, when a component is “directly disposed/directly formed” on another component, it indicates that a third component is not disposed between one component and another component. That is, when a component is “directly placed/directly formed” on another component, it indicates that a component is in “contact” with another component.

Meanwhile, although not shown, in an aspect, a filling layer (not shown) may be disposed between the display panel DP and the light control panel OP. The display panel DP and the light control panel OP may be located to be spaced apart with the filling layer (not shown) therebetween. In this case, the light control panel OP may be manufactured in a separate process and then provided on the display panel DP.

In an aspect, the display panel DP may be referred to as a lower panel or a lower display substrate, and the light control panel OP may be referred to as an upper panel or an upper display substrate.

In the display module DM of an aspect, the base layer BS may be a support substrate provided with the circuit layer DP-CL and the display layer DP-ED. The circuit layer DP-CL includes at least one insulating layer and a circuit element. The circuit element includes signal lines, pixel driving circuits, and the like. The circuit layer DP-CL may be formed through a process of forming an insulating layer, a semiconductor layer, and a conductive layer by coating, vapor deposition, and the like, and a process of patterning the insulating layer, the semiconductor layer, and the conductive layer by photolithography.

The display layer DP-ED includes display elements. The display device may include a light emitting element that generates light and provides the light to the light control panel OP. The display panel DP including the display layer DP-ED may provide source light to the light control panel OP disposed on an upper portion

The light control panel OP may convert the wavelength of light provided from the display panel DP or transmit a portion of the provided light. The light control panel OP may include a light control portion that converts or transmits wavelengths, and structures designed to increase the conversion efficiency of emitted light.

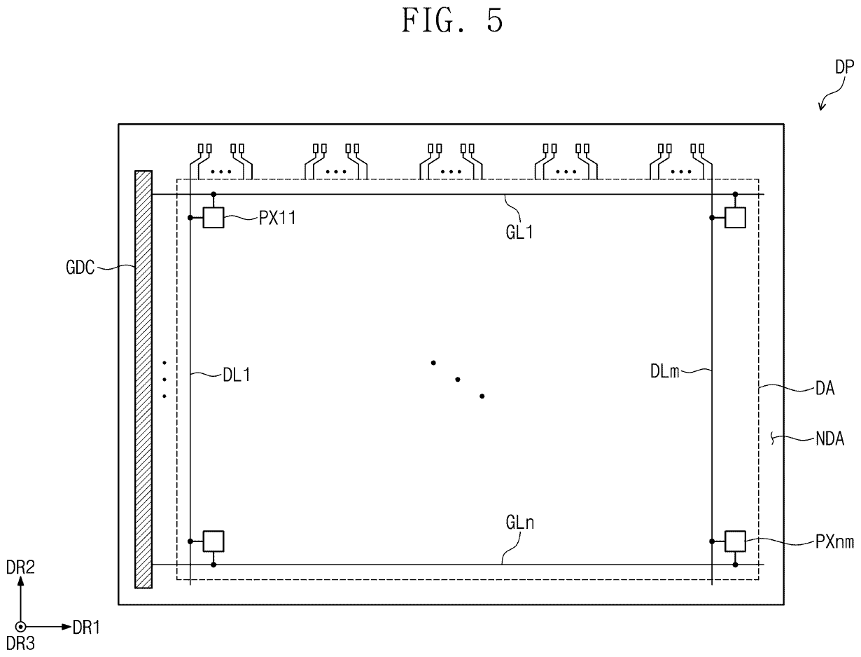

FIG. 5 is a plan view of a display panel according to an aspect.

FIG. 5 shows a planar arrangement relationship of signal lines GL1 to GLn and DL1 to DLm and pixels PX11 to PXnm. The signal lines GL1 to GLn and DL1 to DLm may include a plurality of gate lines GL1 to GLn and a plurality of data lines DL1 to DLm.

The pixels PX11 to PXnm are each connected to a corresponding gate line among the plurality of gate lines GL1 to GLn and a corresponding data line among the plurality of data lines DL1 to DLm. The pixels PX11 to PXnm may each include a pixel driving circuit and a display element. More various types of signal lines may be provided in the display panel DP according to the configuration of the pixel driving circuits of the pixels PX11 to PXnm.

FIG. 5 shows the pixels PX11 to PXnm in a matrix form, but is not limited thereto. The pixels PX11 to PXnm may be disposed in a Pentile® form. For example, points at which the pixels PX11 to PXnm are disposed may correspond to vertices of a diamond. A gate driving circuit GDC may be integrated on the display panel DP through an oxide silicon gate (OSG) driver circuit process or an amorphous silicon gate (ASG) driver circuit process.

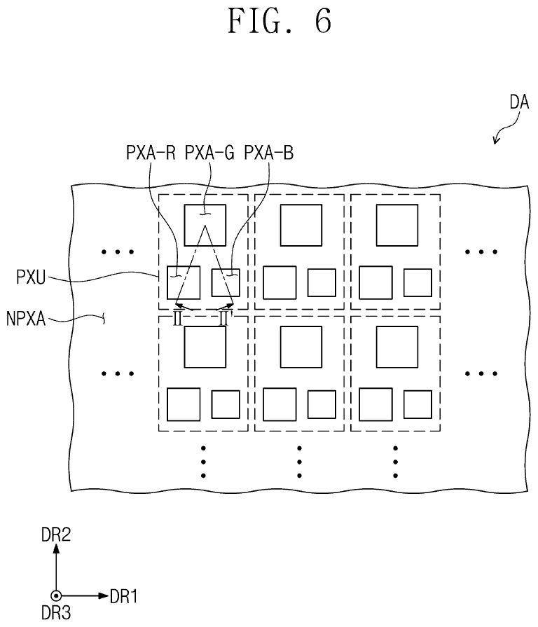

FIG. 6 is a plan view enlarging a portion of a display region in a display module according to an aspect.

Referring to FIG. 6, in an aspect, pixel units PXU may each be arranged in the first direction DR1 and the second direction DR2. In an aspect, the pixel units PXU may include a first pixel, a second pixel, and a third pixel, which emit light in different wavelength ranges. Red light, green light, and blue light may be emitted from the first pixel, the second pixel, and the third pixel, respectively. In FIG. 6, a first pixel region PXA-R, a second pixel region PXA-G, and a third pixel region PXA-B are shown to represent the first pixel, the second pixel, and the third pixel, respectively. The first pixel region PXA-R may be a region in which light generated from the first pixel is provided to the outside, the second pixel region PXA-G may be a region in which light generated from the second pixel is provided to the outside, and the third pixel region PXA-B may be a region in which light generated from the third pixel is provided to the outside. The first to third pixel regions PXA-R, PXA-G, and PXA-B may not overlap and be separated from one another when viewed on a plane.

In an aspect, the first pixel region PXA-R may be a red light emitting region emitting red light, the second pixel region PXA-G may be a green light emitting region emitting green light, and the third pixel region PXA-B may be a blue light emitting region emitting blue light. However, the aspects of this disclosure are not limited thereto. The display region DA may further include a pixel region that emits white light, in addition to the first to third pixel regions PXA-R, PXA-G, and PXA-B.

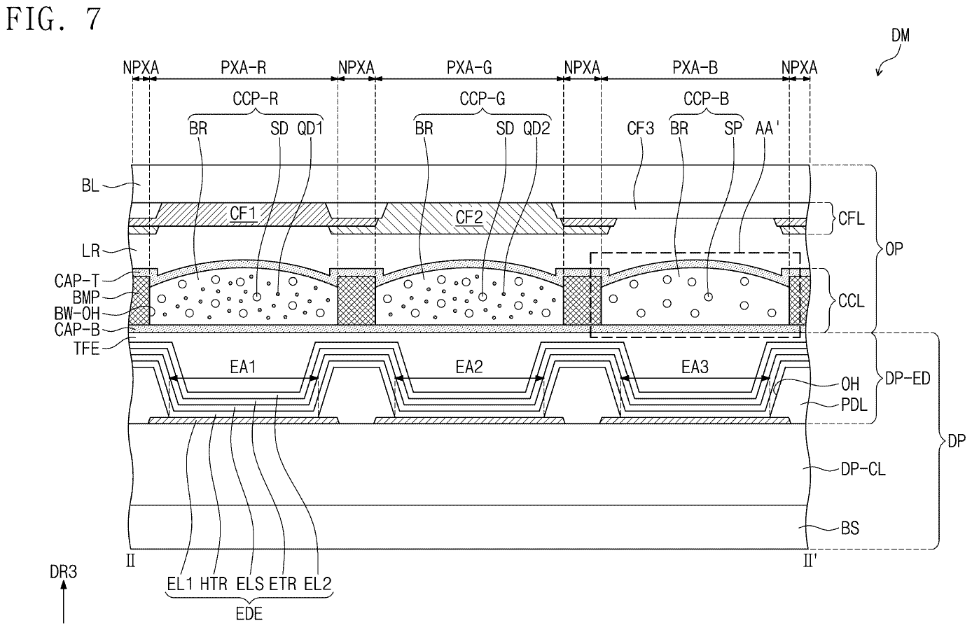

The peripheral region NPXA may be disposed to surround each of the first pixel region PXA-R, the second pixel region PXA-G, and the third pixel region PXA-B. In addition, a peripheral region NPXA may be disposed among the first to third pixel regions PXA-R, PXA-G, and PXA-B. The peripheral region NPXA may set a border among the first to third pixel regions PXA-R, PXA-G, and PXA-B to prevent the first to third pixel regions PXA-R, PXA-G, and PXA-B from being color mixed. For example, to prevent color mixing between the first to third pixel regions PXA-R, PXA-G, and PXA-B, a pixel defining film PDL (see FIG. 7) or a division pattern BMP (see FIG. 7) may be disposed in the peripheral region NPXA.

FIG. 6 shows, as an example, a display module DM that includes the first to third pixel regions PXA-R, PXA-G, and PXA-B having the same planar shape and having different planar areas, but the aspects of this disclosure are not limited thereto. The first to third pixel regions PXA-R, PXA-G, and PXA-B may all have an area of the same size, or at least one type of pixel region may have an area of a different size from the other types of pixel regions. The areas of the first to third pixel regions PXA-R, PXA-G, and PXA-B may be set according to the color of emitted light.

Referring to FIG. 6, the first to third pixel regions PXA-R, PPXA-G, and PXA-B may have a rectangular shape when viewed on a plane. However, the aspect is not limited thereto, and when view on a plane, the first to third pixel regions PXA-R, PXA-G, and PXA-B may have any other polygonal shapes (including substantially polygonal shapes) such as a rhombus or a pentagon. The first to third pixel regions PXA-R, PXA-G, and PXA-B may have a rectangular shape (a substantially rectangular shape) having rounded corners when viewed on a plane.

FIG. 6 shows, as an example, that the second pixel region PXA-G is disposed in a first row, and the first pixel region PXA-R and the third pixel region PXA-B are disposed in a second row, but the aspects of this disclosure are not limited thereto, and the arrangement of the first to third pixel regions PXA-R, PXA-G, and PXA-B may be variously changed. For example, the first to third pixel regions PXA-R, PXA-G, and PXA-B may be disposed in the same row.

For example, the plurality of pixel regions PXA-R, PXA-G, and PXA-B may be arranged in the form of a stripe or may be arranged in the form of a pentile (PENTILE™) or a diamond (Diamond Pixel™). However, the aspect is not limited thereto, and the order and arrangement that the plurality of pixel regions PXA-R, PXA-G, and PXA-B are arranged come with varied combination according to display quality characteristics required for the display module DM.

FIG. 7 is a cross-sectional view showing a portion of a display module according to an aspect. FIG. 7 may be a cross-sectional view showing a portion corresponding to line II-II′ of FIG. 6.

Referring to FIG. 7, in an aspect, the display panel DP may include a base layer BS, a circuit layer DP-CL disposed on the base layer, and a display layer DP-ED disposed on the circuit layer DP-CL. In addition, the display layer DP-ED may include a pixel defining film PDL, a light emitting element EDE, and an encapsulation layer TFE. The encapsulation layer TFE may cover an upper portion of the light emitting element EDE.

In the display module DM according to an aspect, the display panel DP may be a light emitting display panel. For example, the display panel DP may be an organic electroluminescence display panel. When the display panel DP is an organic electroluminescence display panel, the display layer DP-ED may include an organic electroluminescence element as the light emitting element EDE. However, the aspects of this disclosure are not limited thereto. For example, the display layer DP-ED may include a quantum dot light emitting element as the light emitting element EDE. In addition, the display layer DP-ED may include a micro LED element and/or a nano LED element as the light emitting element EDE.

The display panel DP may provide source light. The light emitting element EDE may generate source light. The source light generated and emitted from the light emitting element EDE may be provided to the light control panel OP, and at least a portion of the source light may be converted into light having a wavelength different from a wavelength of the source light in the light control layer CCL of the light control panel OP, or at least a portion of the source light may be transmitted without wavelength conversion.

In the display panel DP, the base layer BS may be a member providing a base surface in which the circuit layer DP-CL and the display layer DP-ED are disposed. The base layer BS may be a glass substrate, a metal substrate, a polymer substrate, or the like. However, the aspects of this disclosure are not limited thereto, and the base layer BS may be an inorganic layer, a functional layer, or a composite material layer.

The base layer BS may have a multilayer structure. For example, the base layer BS may have a three-layer structure of a polymer resin layer, an adhesive layer, and a polymer resin layer. In particular, the polymer resin layer may include a polyimide-based resin. In addition, the polymer resin layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin. Meanwhile, as used herein, “a-based” resin may be considered as including a functional group of “a”.

The circuit layer DP-CL may be disposed on the base layer BS. The circuit layer DP-CL may include an insulating layer, a semiconductor pattern, a conductive pattern, a signal line, and the like. The insulating layer, the semiconductor layer, and the conductive layer are formed on the base layer BS through coating or deposition, and subsequently, the insulating layer, the semiconductor layer, and the conductive layer may be selectively patterned through multiple times of a photolithography process. Then, the semiconductor pattern, the conductive pattern, and the signal line included in the circuit layer DP-CL may be formed. In an aspect, the circuit layer DP-CL may include a transistor, a buffer layer, and a plurality of insulating layers. In an aspect, the circuit layer DP-CL may include a plurality of transistors (not shown). The transistors (not shown) may each include a control electrode, an input electrode, and an output electrode. For example, the circuit layer DP-CL may include a switching transistor and a driving transistor for driving the light emitting element EDE of the display layer DP-ED.

The display layer DP-ED may include the light emitting element EDE as a display element. The light emitting element EDE may generate source light. In an aspect, the source light may include blue light and green light. In addition, in an aspect, the source light may be white light, and in this case, the source light may include blue light, green light, and red light. Meanwhile, alternatively, the source light may include only light in blue wavelength ranges.

In an aspect, the display layer DP-ED includes a light emitting element EDE including a first electrode EL1, a second electrode EL2 facing the first electrode EL1, and a light emitting portion ELS disposed between the first electrode EL1 and the second electrode EL2. In an aspect, the light emitting portion ELS may include an organic light emitting material, and the light emitting element EDE may be an organic electroluminescence element. The light emitting element EDE may further include a hole transport region HTR and an electron transport region ETR. Meanwhile, although not shown, the light emitting element EDE may further include a capping layer (not shown) disposed on an upper portion of the second electrode EL2.

The display layer DP-ED may include the pixel defining film PDL. The pixel defining film PDL may be disposed on the circuit layer DP-CL and may cover a portion of the first electrode EL1. A light emitting opening OH is defined in the pixel defining film PDL. The light emitting opening OH of the pixel defining film PDL allows at least a portion of the first electrode EL1 to be exposed. In the present aspect, light emitting regions EA1, EA2, and EA-3 are defined corresponding to a partial region of the first electrode EL1 exposed by the light emitting opening OH.

The pixel defining film PDL may be formed of a polymer resin. For example, the pixel defining film PDL may be formed including a polyacrylate-based resin or a polyimide-based resin. In addition, the pixel defining film PDL may be formed by further including an inorganic material in addition to the polymer resin. Meanwhile, the pixel defining film PDL may be formed including a light absorbing material, or may be formed including a black pigment or a black dye. The pixel defining film PDL formed including a black pigment or a black dye may implement a black pixel defining film. When forming the pixel defining film PDL, carbon black may be used as a black pigment or a black dye, but the aspects of this disclosure are not limited thereto.

In addition, the pixel defining film PDL may be formed of an inorganic material. For example, the pixel defining film PDL may be formed of an inorganic material such as silicon nitride (SiNₓ), silicon oxide (SiOₓ), or silicon nitride (SiOₓN_{y}).

The display panel DP may include a first light emitting region EA1, a second light emitting region EA2, and a third light emitting region EA3. The first light emitting region EA1, the second light emitting region EA2, and the third light emitting region EA3 may be regions separated by the pixel defining film PDL. The first light emitting region EA1, the second light emitting region EA2, and the third light emitting region EA3 may respectively correspond to the first pixel region PXA-R, the second pixel region PXA-G, and the third pixel region PXA-B. Meanwhile, as described herein, the term “correspond” indicates that two components overlap when viewed in the thickness direction DR3 of the display panel DD, and is not limited to the same area.

The light emitting regions EA1, EA2, and EA3 may overlap the pixel regions PXA-R, PXA-G, and PXA-B. When viewed on a plane, the pixel regions PXA-R, PXA-G, and PXA-B separated by the division pattern BMP may have a greater area than the light emitting regions EA1, EA2, and EA3 separated by the pixel defining film PDL.

In the light emitting element EDE, the first electrode EL1 is disposed on the circuit layer DP-CL. The first electrode EL1 may be exposed in the light emitting opening OH of the pixel defining film PDL. The first electrode EL1 may be an anode or a cathode. In addition, the first electrode EL1 may be a pixel electrode. The first electrode EL1 may be a transmissive electrode, a transflective electrode, or a reflective electrode.

The second electrode EL2 may be disposed on the first electrode EL1. The second electrode EL2 may be a cathode or an anode. In an aspect, when the first electrode EL1 is an anode, the second electrode EL2 may be a cathode, and when the first electrode EL1 is a cathode, the second electrode EL2 may be an anode. The second electrode EL2 may be a common electrode. However, the aspect is not limited thereto. The second electrode EL2 may be a transmissive electrode, a transflective electrode, or a reflective electrode.

In an aspect, the light emitting portion ELS may be provided as a single emission layer or as a light emitting stack in which a plurality of light emitting units are stacked. When the light emitting portion ELS is a light emitting stack in which a plurality of light emitting units are stacked, the light emitting portion ELS may include two or more light emitting stacks that are distinct from each other and stacked in the third direction DR3, which is a thickness direction. The light emitting units may each include at least one emission layer.

For example, in an aspect, the light emitting portion ELS may include at least one blue light emitting unit that emits blue light and at least one green light emitting unit that emits green light. In addition, the light emitting portion ELS may include a charge generation layer disposed between the light emitting units. Meanwhile, the aspects of this disclosure are not limited thereto, and the light emitting portion ELS may include a blue light emitting unit that emits blue light, a green light emitting unit that emits green light, and a red light emitting unit that emits red light. In addition, alternatively, the light emitting portion ELS may include a plurality of light emitting units that emit light in the same wavelength range.

An emission layer included in the light emitting portion ELS may have a single layer formed of a single material, a single layer formed of a plurality of materials different from each other, or a multi-layered structure that has a plurality of layers formed of a plurality of materials different from each other. The emission layer may include a fluorescent or phosphorescent material. In the light emitting element EDE of an aspect, the light emitting portion ELS may include an organic light emitting material, an organometallic complex, or quantum dots as a light emitting material.

The light emitting portion ELS may commonly disposed in the first to third light emitting regions EA1, EA2, and EA3 and a non-light emitting region. Herein, the non-light emitting region may be a portion that overlaps the pixel defining film PDL. However, the aspects of this disclosure are not limited thereto, and in an aspect, the light emitting portion ELS may be disposed in the light emitting opening OH. That is, the light emitting portion ELS may be separately disposed to correspond to each of the light emitting regions EA1, EA2, and EA3 which are separated by the pixel defining film PDL.

In the light emitting element EDE, the hole transport region HTR may be disposed on the first electrode EL1. The hole transport region HTR may be commonly disposed in the first to third light emitting regions EA1, EA2, and EA3 and the non-light emitting region. In an aspect, the hole transport region HTR is a common layer and may be disposed to overlap a plurality of pixel units PXU of the display region DA shown in FIG. 6. However, the aspects of this disclosure not limited thereto, and the hole transport region HTR may be disposed separately to correspond to each of the first to third light emitting regions EA1, EA2, and EA3. The hole transport region HTR may include at least one of a hole transport layer, a hole injection layer, or an electron blocking layer.

The electron transport region ETR may be disposed on the light emitting portion ELS. The electron transport region ETR may include at least one of an electron injection layer, an electron transport layer, or a hole blocking layer. The electron transport region ETR may be commonly disposed in the first to third light emitting regions EA1, EA2, and EA3 and the non-light emitting region. However, the aspects of this disclosure are not limited thereto, and the electron transport region ETR may be disposed separately to correspond to each of the first to third light emitting regions EA1, EA2, and EA3.

The encapsulation layer TFE may be disposed on the second electrode EL2. Alternatively, when the light emitting element EDE includes a capping layer (not shown), the encapsulation layer TFE may be disposed on the capping layer (not shown). The encapsulation layer TFE may cover the light emitting element EDE.

The encapsulation layer TFE may be a thin film encapsulation layer. The encapsulation layer TFE may be a single layer or a stack layer of a plurality of layers. The encapsulation layer TFE includes at least one insulating layer. The encapsulation layer TFE according to an aspect may include at least one inorganic film (hereinafter, an encapsulation inorganic film). In addition, the encapsulation layer TFE according to an aspect may include at least one organic film (hereinafter, an encapsulation organic film) and at least one encapsulation inorganic film.

The encapsulation inorganic film protects the light emitting element EDE from moisture/oxygen, and the encapsulation organic film protects the light emitting element EDE from foreign substances such as dust particles. The encapsulation inorganic film may include silicon nitride, silicon oxy nitride, silicon oxide, titanium oxide, aluminum oxide, and the like, but is not particularly limited thereto. The encapsulation organic film may include an acrylic compound, an epoxy-based compound, and the like. The encapsulation organic film may include a photopolymerizable organic material, and is not particularly limited.

The light control panel OP may be disposed on the display panel DP. In the display module DM of an aspect shown in FIG. 7, the light control panel OP may be directly disposed on the display panel DP. However, the aspects of this disclosure are not limited thereto, and the display module DM may include a filling layer (not shown) disposed between the display panel DP, which is a lower panel, and the light control panel OP, which is an upper panel, as described above.

In an aspect, the light control panel OP may include a light control layer CCL. In an aspect shown in FIG. 7, the light control layer CCL may be disposed on the encapsulation layer TFE. In an aspect, the light control panel OP may include a low refractive layer LR, a color filter layer CFL, and a base substrate BL, in addition to the light control layer CCL.

In an aspect, the light control layer CCL may include quantum dots. The light control layer CCL may include a plurality of light control portions CCP-R, CCP-G, and CCP-B. At least one of the first to third light control portions CCP-R, CCP-G, and CCP-B may include quantum dots that convert the optical properties of source light.

In an aspect, the light control layer CCL may include a plurality of light control portions CCP1, CCP2, and CCP3. The light control layer CCL may be formed through inkjet printing. For example, each of the first light control portion CCP-R, the second light control portion CCP-G, and the third light control portion CCP-B may be formed by supplying the corresponding light control portion composition through a nozzle of an inkjet printing device and then performing a curing process.

The light control layer CCL may include a first light control portion CCP-R corresponding to the first pixel region PXA-R, a second light control portion CCP-G corresponding to the second pixel region PXA-G, and a third light control portion CCP-B corresponding to the third pixel region PXA-B. The first light control portion CCP-R may be a red light control portion that emits red light, and the second light control portion CCP-G may be a green light control portion that emits green light. The third light control portion CCP-B may be a blue light control portion that emits blue light. Alternatively, the third light control portion CCP-B may be a transmission light control portion that transmits and emits source light.

The first light control portion CCP-R wavelength-converts the source light provided from the display layer DP-ED to emit red light. In addition, a portion of the source light may be emitted by passing through the first light control portion CCP-R without being wavelength-converted. In addition, the second light control portion CCP-G wavelength-converts the source light provided from the display layer DP-ED to emit green light. In addition, a portion of the source light may be emitted by passing through the second light control portion CCP-G without being wavelength-converted. In an aspect, the first light control portion CCP-R and the second light control portion CCP-G may include quantum dots that wavelength-convert at least a portion of the source light.

The third light control portion CCP-B may be a portion that transmits and emits source light provided from the display layer DP-ED. The third light control portion CCP-B may not include quantum dots. However, the aspects of the this disclosure are not limited thereto, and the third light control portion CCP-B may further include quantum dots that wavelength-convert a portion of the source light provided from the display layer DP-ED to emit blue light, and may emit light in a different wavelength range from the first light control portion CCP-R and the second light control portion CCP-G.

A first quantum dot QD1 may convert the optical properties of at least a portion of the source light provided from the display layer DP-ED. For example, the first quantum dot QD1 may convert light in a blue wavelength range of the source light into red light. The first quantum dot QD1, which converts the wavelength of the provided light to emit red light, may be referred to as a red quantum dot. In addition, in an aspect, a portion of the first quantum dot QD1 may convert light in a green wavelength range of the source light into red light.

A second quantum dot QD2 may be different from the first quantum dot QD1. The second quantum dot QD2 may convert the optical properties of at least a portion of the source light provided from the display layer DP-ED. For example, the second quantum dot QD2 may convert light in a blue wavelength range of the source light into green light. The second quantum dot QD2, which converts the wavelength of the provided light to emit green light, may be referred to as a green quantum dot.

Quantum dots included in the light control layer CCL of an aspect are crystals of a semiconductor compound. The descriptions of quantum dots, which will be described later, may also apply to the first quantum dot QD1 and the second quantum dot QD2.

Quantum dots may emit light of various light emitting wavelengths depending on the size of crystal. The quantum dots may emit light of various light emitting wavelengths by regulating an element ratio in a compound of the quantum dots.

The quantum dots may have a diameter of, for example, about 1 nm to about 10 nm. The quantum dots may be synthesized through a wet chemical process, a metal organic chemical vapor deposition process, a molecular beam epitaxy process, or a process similar thereto.

Among the quantum dot manufacturing processes, the wet chemical process is a method of mixing an organic solvent and a precursor material and then growing a quantum dot particle crystal. When the quantum dot particle crystal grows, the organic solvent naturally serves as a dispersant coordinated to a surface of the quantum dot crystal and may control the growth of the particle crystal. Therefore, the wet chemical process is easier than vapor deposition methods such as metal organic chemical vapor deposition (MOCVD) or molecular beam epitaxy (MBE), and may control the growth of quantum dot particles through a low-cost process.

A core of the quantum dots may be selected from a Group II-VI compound, a Group III-V compound, a Group III-VI compound, a Group I-III-VI compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. Meanwhile, the Group II-VI semiconductor compound may further include a Group I metal and/or a Group IV element. The Group I-II-VI compound may be selected from CuSnS or CuZnS, and the Group II-IV-VI compound may be selected from ZnSnS and the like. The Group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ and In₂Se₃, a ternary compound such as InGaS₃ and InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, or a mixture thereof, or a quaternary compound such as AgInGaS₂ and CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. Meanwhile, the Group III-V compound may further include a Group II metal. For example, InZnP and the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Examples of the Group II-IV-V semiconductor compound may be a ternary compound selected from the group consisting of ZnSnP, ZnSnP₂, ZnSnAs₂, ZnGeP₂, ZnGeAs₂, CdSnP₂, and CdGeP₂, and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and quaternary compound may be present in particles at a uniform concentration or a non-uniform concentration. That is, a formula representing quantum dots indicates the types of elements included in a quantum dot compound, and element ratios in the compound may be different. For example, AgInGaS₂ may indicate AgInₓGa₁₋ₓS₂ (x is a real number between 0 and 1).

In this case, the binary compound, the ternary compound, or the quaternary compound may be present in particles having a uniform concentration distribution, or may be present in the same particles having a partially different concentration distribution. In addition, a core/shell structure in which one quantum dot surrounds another quantum dot may be present. The core/shell structure may have a concentration gradient in which the concentration of an element present in the shell becomes lower towards the core.

In some aspects, the quantum dots may have the above-described core/shell structure including a core having nano-crystals and a shell surrounding the core. The shell of the quantum dots may serve as a protection layer to prevent the chemical deformation of the core so as to maintain semiconductor properties, and/or a charging layer to impart electrophoresis properties to the quantum dots. The shell may be single-layered or multi-layered. Examples of the shell of the quantum dots may be a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but the aspects of this disclosure are not limited thereto.

In addition, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but the aspects of this disclosure are not limited thereto.

The quantum dots may have, in a light emitting wavelength spectrum, a full width of half maximum (FWHM) of about 45 nm or less, preferably about 40 nm or less, and more preferably about 30 nm or less, and in this range, the color purity or the color reproducibility may be improved. In addition, light emitted through the quantum dots is emitted in all directions, and thus a wide viewing angle may be improved.

In addition, the form of the quantum dots is not particularly limited as long as it is a form commonly used in the art, but more specifically, a quantum dot in the form of spherical, pyramidal, multi-arm, or cubic nanoparticles, nanotubes, nanowires, nanofibers, nanoplatelets, and the like may be used.

As the size of the quantum dots or the ratio of elements in the quantum dot compound is regulated, the energy band gap may be accordingly controlled to obtain light of various wavelengths from a layer containing quantum dots. Therefore, by using the quantum dots as described above (using quantum dots of different sizes or having different element ratios in the quantum dot compound), a light control portion emitting light of various wavelengths may be obtained.

In addition, the light control layer CCL may further include scatterers SP. For example, the first light control portion CCP1 may include the first quantum dot QD1 and the scatterers SP, the second light control portion CCP2 may include the second quantum dot QD2 and the scatterers SP, and the third light control portion CCP3 may not include a quantum dot but may include the scatterers SP.

The scatterers SP may be inorganic particles. For example, the scatterers SP may include at least one of TiO₂, SiO₂, BaSO₄, BaO, ZnS, ZnO, Al₂O₃, CaCO₃, or hollow silica. The scatterers SP may include any one of TiO₂, SiO₂, BaSO₄, BaO, ZnS, ZnO, Al₂O₃, CaCO₃, and hollow silica, or may be a mixture of two or more materials selected from TiO₂, SiO₂, BaSO₄, BaO, ZnS, ZnO, Al₂O₃, CaCO₃, and hollow silica.

The light control layer CCL may include a base resin BR. The first light control portion CCP1, the second light control portion CCP2, and the third light control portion CCP3 may each include a base resins BR for dispersing the quantum dots QD1 and QD2 and the scatterers SP. In an aspect, the first light control portion CCP1 may include the first quantum dot QD1 and the scatterers SP dispersed in the base resin BR, the second light control portion CCP2 may include the second quantum dot QD2 and the scatterers SP dispersed in the base resin BR, and the third light control portion CCP3 may include the scatterers SP dispersed in the base resin BR.

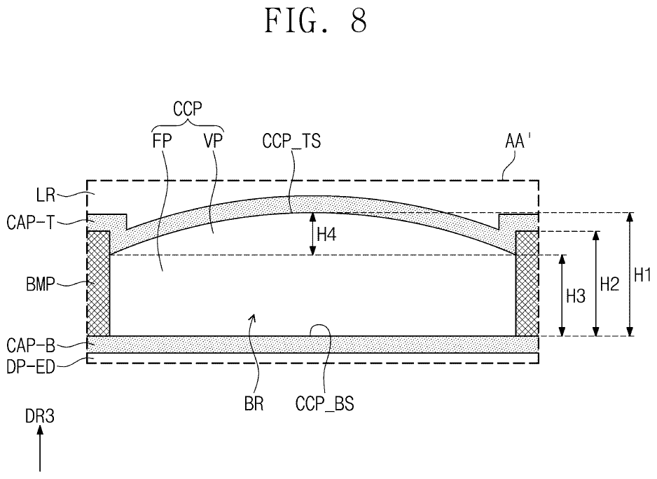

The base resin BR is a medium in which the quantum dots QD1 and QD2 and the scatterer SP are dispersed, and may be formed of various resin compositions, which may be generally referred to as a binder. Base resins BR1, BR2, and BR3 may be transparent resins. In an aspect, the base resin included in each of the first light control portion CCP1, the second light control portion CCP2, and the third light control portion CCP3 may be the same or different. Specific details of the base resin BR will be described below in FIG. 8. In addition, the light control layer CCL may include a division pattern BMP. The division pattern BMP may be configured to separate a plurality of light control portions CCP-R, CCP-G, and CCP-B. The division pattern BMP may include a base resin and an additive. The base resin may be formed of various resin compositions that may be generally referred to as binders. The additive may include a coupling agent and/or a photo-initiator. The additive may further include a dispersant.

The division pattern BMP may include a black coloring agent to block light. The division pattern BMP may include a black dye and a black pigment mixed with a base resin. In an aspect, the black component may include carbon black, a metal such as chromium, or an oxide thereof.

An opening BW-OH corresponding to the light emitting opening OH may be defined in the division pattern BMP. When viewed on a plane, the opening BW-OH overlaps the light emitting opening OH and has a larger area than the light emitting opening OH. That is, the opening BW-OH may have a larger area than the light emitting regions EA1, EA2, and EA3 defined by the light emitting opening OH. The light control portions CCP-R, CCP-G, and CCP-B may be disposed inside the opening BW-OH.

In the light control panel OP according to an aspect shown in FIG. 7, the base substrate BL may be a member that provides a reference surface on which the color filter layer CFL, the low refractive layer LR, and the light control layer CCL are disposed. The base substrate BL may be a glass substrate, a metal substrate, a plastic substrate, and the like. However, the aspects of this disclosure are not limited thereto, and the base substrate BL may be an inorganic layer, an organic layer, or a composite material layer. In addition, unlike what is shown, the base substrate BL may be omitted in an aspect.

Although not shown, an anti-reflection layer may be disposed on the base substrate BL. The anti-reflection layer may be a layer that reduces the reflectance of external light incident from the outside. The anti-reflection layer may be a layer that selectively transmits light emitted from the display module DM. In an aspect, the anti-reflection layer may be a single layer including a dye and/or a pigment dispersed in a base resin. The anti-reflection layer may be provided as a single continuous layer that entirely overlaps the first to third pixel regions PXA-R, PXA-G, and PXA-B.

The anti-reflection layer may not include a polarizing layer. Accordingly, light that passes through the anti-reflection layer and is incident on the side of the display layer DP-ED may be unpolarized light. The display layer DP-ED may receive unpolarized light from an upper portion of the anti-reflection layer.

In an aspect, the light control layer CCL may include barrier layers CAP-B and CAP-T. The barrier layers CAP-B and CAP-T may serve to prevent penetration of moisture and/or oxygen (hereinafter, referred to as ‘moisture/oxygen’) and improve optical properties of the light control panel OP by regulating a refractive index. The barrier layers CAP-B and CAP-T may be disposed on an upper portion or a lower portion of the light control layer CCL. The barrier layers CAP-B and CAP-T may be disposed on the upper or lower surface of the light control portions CCP-R, CCP-G, and CCP-B to prevent the light control portions CCP-R, CCP-G, and CCP-B from being exposed to moisture/oxygen, and in particular, may prevent quantum dots included in the light control portions CCP-R, CCP-G, and CCP-B from being exposed to moisture/oxygen. The barrier layers CAP-B and CAP-T may also protect the light control portions CCP-R, CCP-G, and CCP-B from external shock.

In an aspect, the first barrier layer CAP-T may be located to be spaced apart from the display layer DP-ED with the light control portions CCP-R, CCP-G, and CCP-B therebetween. That is, the first barrier layer CAP-T may be disposed on the upper surface of the light control portions CCP-R, CCP-G, and CCP-B. In an aspect, the light control layer CCL may further include a second barrier layer CAP-B disposed between the light control portions CCP-R, CCP-G, and CCP-B and the display layer DP-ED. In an aspect, the first barrier layer CAP-T may cover the upper surface of the light control portions CCP-R, CCP-G, and CCP-B adjacent to the low refractive layer LR, and the second barrier layer CAP-B may cover the lower surface of the light control portions CCP-R, CCP-G, and CCP-B adjacent to the display layer DP-ED. Meanwhile, herein, the “upper surface” may be a surface placed on an upper portion with respect to the third direction DR3, and the “lower surface” may be a surface placed on a lower portion with respect to the third direction DR3.

In addition, the first barrier layer CAP-T and the second barrier layer CAP-B may cover the light control portions CCP-R, CCP-G, and CCP-B and one side of the division pattern BMP.

The second barrier layer CAP-T may cover one surface of the division pattern BMP and the light control portions CCP-R, CCP-G, and CCP-B, which are adjacent to the low refractive layer LR. The first barrier layer CAP-T may be disposed to follow a step between the division pattern BMP and the light control portions CCP-R, CCP-G, and CCP-B.

The first barrier layer CAP-T and the second barrier layer CAP-B may be formed to include an inorganic material. In an aspect, the first barrier layer CAP-T includes silicon oxynitride (SiON). Both the first barrier layer CAP-T and the second barrier layer CAP-B may include silicon oxynitride. However, the aspects of this disclosure are not limited thereto, and the first barrier layer CAP-T may include silicon oxynitride, and the second barrier layer CAP-B may include silicon oxide (SiOₓ).

The light control panel OP may further include a color filter layer CFL disposed on the light control layer CCL. The color filter layer CFL includes at least one of the color filters CF1, CF2, or CF3. The color filter transmits light having a specific wavelength range and blocks light having a wavelength other than the specific wavelength range. In an aspect, the first color filter CF1 may be a red filter that transmits red light, the second color filter CF2 may be a green filter that transmits green light, and the third color filter CF3 may be a blue filter that transmits blue light.

The filters CF1, CF2, and CF3 each include a polymer photosensitive resin and a colorant. The colorant may include pigments or dyes. The first color filter CF1 may contain a red pigment or a red dye, the second color filter CF2 may contain a green pigment or a green dye, and the third color filter CF3 may contain a blue pigment or a blue dye. In an alternate aspect, the third color filter CF3 may not contain pigments or dyes.

The first to third color filters CF1, CF2, and CF3 may be disposed to correspond to the first pixel region PXA-R, the second pixel region PXA-G, and the third pixel region PXA-B, respectively. In addition, the first to third color filters CF1, CF2, and CF3 may be disposed to overlap the first to third light control portions CCP-R, CCP-G, and CCP-B, respectively.

Referring to FIG. 7, in the peripheral region NPXA, the plurality of color filters CF1, CF2, and CF3 that transmit different light may be disposed to overlap. In the peripheral region NPXA, the plurality of color filters CF1, CF2, and CF3 may be disposed to overlap in the third direction DR3, which is the thickness direction, to distinguish a border between the adjacent pixel regions PXA-R, PXA-G, and PXA-B. Unlike what is shown, the color filter layer CFL may include a light blocking portion (not shown) for distinguishing a border between the adjacent color filters CF1, CF2, and CF3. The light blocking portion (not shown) may be formed of a blue filter or may include an organic light blocking material or an inorganic light blocking material that includes a black pigment or a black dye.

Referring to FIG. 7, the light control panel OP may further include a low refractive layer LR. The low refractive layer LR may be disposed between the light control layer CCL and the color filters CF1, CF2, and CF3. The low refractive layer LR may serve as an optical functional layer that is disposed between the light control portions CCP-R, CCP-G, and CCP-B and the color filters CF1, CF2, and CF3 to increase the light extraction efficiency of light emitted from the light control layer CCL or prevent reflected light from being incident on the light control layer CCL. The low refractive layer LR may have a smaller refractive index than a layer adjacent thereto.

The low refractive layer LR may include at least one inorganic layer. For example, the low refractive layer LR may be formed including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film in which light transmittance is secured. However, the aspects of this disclosure are not limited thereto, and the low refractive layer LR may include an organic layer. The low refractive layer LR may have, for example, a structure in which a plurality of hollow particles are dispersed in an organic polymer resin. The low refractive layer LR may be formed of a single layer or a plurality of layers.

Although not shown, the light control panel OP may further include a buffer layer (not shown). In an aspect, the buffer layer (not shown) may serve as a buffer between the light control layer CCL and the color filter layer CFL. In an aspect, the buffer layer (not shown) may have a shock absorbing function and the like, and may increase the strength of the display module DM. In addition, the buffer layer (not shown) may serve as a protection layer that protects the light control layer CCL. The buffer layer (not shown) may be formed from a filler resin including a polymer resin. For example, the buffer layer (not shown) may be formed from a filling layer resin including an acryl-based resin or an epoxy-based resin. Alternatively, the buffer layer (not shown) may be an inorganic material layer including at least one inorganic material among silicon nitride, silicon oxide, and silicon oxynitride.

FIG. 8 is a cross-sectional view enlarging a portion of a display module according to an aspect. FIG. 8 shows an enlarged region AA′ shown in FIG. 7. However, the description of FIG. 8 described below is not limited to the third light control portion CCP-B in region AA′ shown in FIG. 7, and is applied to any one or more light control portions CCP among the first light control portion CCP-R, the second light control portion CCP-G, and the third light control portion CCP-B in the light control layer CCL. Meanwhile, FIG. 8 is shown without the quantum dots or the scatterers SD dispersed in the base resin portion BR of FIG. 7.

In an aspect, the light control portion CCP has an upper convex surface CCP_TS in a direction away from the display layer DP-ED. The light control portion CCP may have a convex shape in a direction closer to the low refractive layer LR. The light control portion CCP may have a convex shape with respect to the third direction DR3.

A first height H1 of the light control portion CCP may be greater than a second height H2 of the division pattern BMP. Herein, the “height” of a component may indicate a maximum separation distance in the third direction DR3 between a lower surface of the component and an upper surface of the component opposite to the lower surface. For example, the first height H1 of the light control portion CCP is the maximum separation distance in the third direction DR3 between a lower surface CCP_BS of the light control portion CCP and an upper surface CCP_TS of the light control portion CCP. In a further example, the second height H2 of the division pattern BMP is the maximum separation distance in the third direction DR3 between a lower surface of the division pattern BMP and an upper surface of the division pattern BMP. The first height H1 of the light control portion CCP may be about 5 μm to about 15 μm, and the second height H2 of the division pattern BMP may be about 5 μm to about 10 μm. However, the aspects of this disclosure are not limited thereto.

Referring to FIG. 8, the light control portion CCP may include a flat portion FP disposed on the display layer DP-ED, and a convex portion VP disposed on the flat portion FP. The flat portion FP and the convex portion VP may be portions of a single layer formed concurrently through the same process, rather than components formed through different processes. The flat portion FP and the convex portion VP may correspond to components arbitrarily named to distinguish areas of the light control portion CCP. The flat portion FP may indicate a portion with a substantially uniform height in the third direction DR3 when viewed on a plane. An upper surface of the flat portion FP may be a flat surface with respect to the third direction DR3. The convex portion VP may be directly disposed on the flat portion FP. A lower surface of the convex portion VP may be substantially the same surface as the upper surface of the flat portion FP. An upper surface of the convex portion VP may be the upper surface CCP_TS of the light control portion CCP, and the upper surface of the convex portion VP may have a convex shape with respect to the third direction DR3.

The sum of a third height H3 of the flat portion FP and a fourth height H4 of the convex portion VP may be equal to the first height H1 of the light control portion CCP. The fourth height H4 of the convex portion VP may indicate a degree to which the upper surface CCP_TS of the light control portion CCP is convex. The fourth height H4 of the convex portion VP may be about 1 μm to about 3 μm. That is, the maximum separation distance in the third direction DR3 between the upper surface of the flat portion FP and the upper surface of the convex portion VP may be about 1 μm to about 3 μm. However, the aspects of this disclosure are not limited thereto.

The third height H3 of the flat portion FP may be smaller than the second height H2 of the division pattern BMP. The second height H2 of the division pattern BMP may be larger than the third height H3 of the flat portion FP and may be smaller than the first height H1 of the light control portion CCP. The upper surface CCP_TS of the light control portion CCP may include a highest point having a maximum height from the upper surface of the display layer DP-ED, and a lowest point having a minimum height from the upper surface of the display layer DP-ED. The highest point of the upper surface CCP_TS may indicate a point closest to the low refractive layer LR in the third direction DR3. The lowest point of the upper surface CCP_TS may be adjacent to a side surface of the division pattern BMP. The upper surface CCP_TS of the light control portion CCP has a convex shape, and accordingly, the highest point of the upper surface CCP_TS may be defined at a location adjacent to the low refractive layer LR in the third direction DR3 compared to the upper surface of the division pattern BMP, and the lowest point of the upper surface CCP_TS may be defined at a location adjacent to the display layer DP-ED in the third direction DR3 compared to the upper surface of the division pattern BMP.

The light control portion CCP may include a base resin portion BR, and the base resin portion BR may include a polymer derived from a resin composition containing a first monomer. The upper surface CCP_TS of the light control portion CCP may have a convex shape achieved by the first monomer. With respect to 100 parts by weight of the resin composition, the first monomer may range from about 30 parts by weight to about 70 parts by weight. In other words, the resin composition may have 30% by weight to 70% by weight first monomer.

The first monomer includes an expanding monomer. The first monomer may include a carbonate-based compound or a benzoxazine-based compound. For example, the first monomer may include a thiocarbonate-based compound, a cyclic carbonate-based compound, or a benzoxazine-based compound. The first monomer may include a compound represented by any one of Compound Group 1 below. However, aspects are not limited to the types described above, and the first monomer may include any one of the types of expanding monomers as needed.

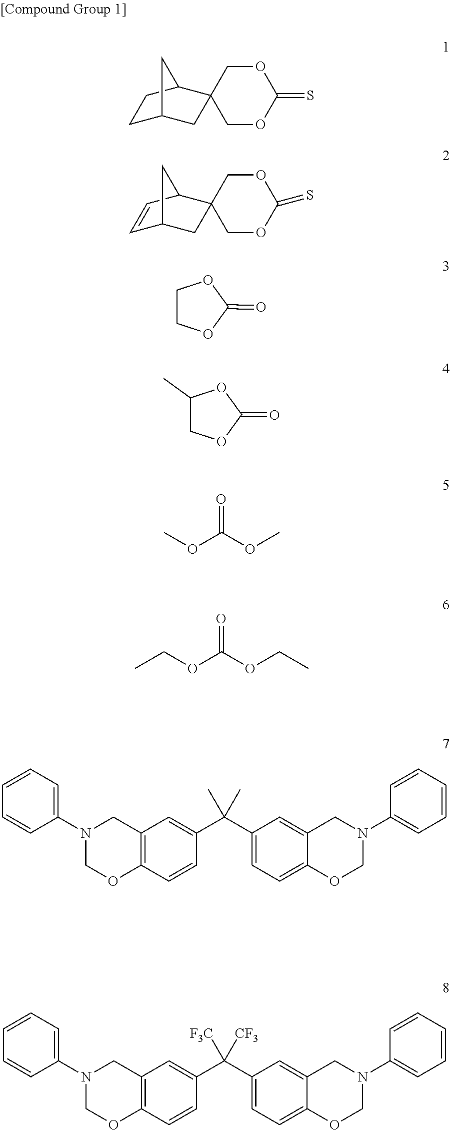

The base resin portion BR may include a polymer derived from a resin composition including a first monomer and a second monomer different from the first monomer. The first monomer may include an expanding monomer, and the second monomer may be hexamethylenediamine (HMDA). With respect to 100 parts by weight of the resin composition, the first monomer may range from about 20 parts by weight to about 70 parts by weight, and the second monomer may range from about 30 parts by weight to about 80 parts by weight. In other words, the resin composition may have about 20 to about 70% by weight first monomer and about 30 to about 80% by weight second monomer. For example, when the first monomer be a thiocarbonate-based compound and the second monomer be hexamethylenediamine, the first monomer may range from about 50 parts by weight to about 60 parts by weight and the second monomer may range from about 30 parts by weight to about 40 parts by weight, with respect to 100 parts by weight of the resin composition. Alternatively, when the first monomer includes a cyclic carbonate-based compound and a benzoxazine-based compound and the second monomer is hexamethylenediamine, the first monomer may range from about 20 parts by weight to about 30 parts by weight and the second monomer may range from about 60 parts by weight to about 70 parts by weight, with respect to 100 parts by weight of the resin composition. In other words, the resin composition may have about 20 to about 30% by weight first monomer and about 60 to about 70% by weight second monomer.

Hereinafter, the results of evaluating the characteristics of the display module according to an aspect of this disclosure will be described with reference to Example, Comparative Example, FIGS. 7, 8, 9A, and 9B. In addition, aspects below are shown only for the understanding of this disclosure, and are not limited thereto.

### (Manufacturing of Display Modules)

Example was manufactured as a display module DM having the structure of FIG. 7. Referring to FIG. 8, Example includes a light control portion CCP in which an upper surface CCP_TS has a convex shape with respect to a third direction DR3, a convex shape formed by including an expanding monomer in the resin composition used to form the base resin portion BR. In Example, a fourth height H4 indicating a degree of convexity of the upper surface CCP_TS of the light control portion CCP may be about 2 μm.

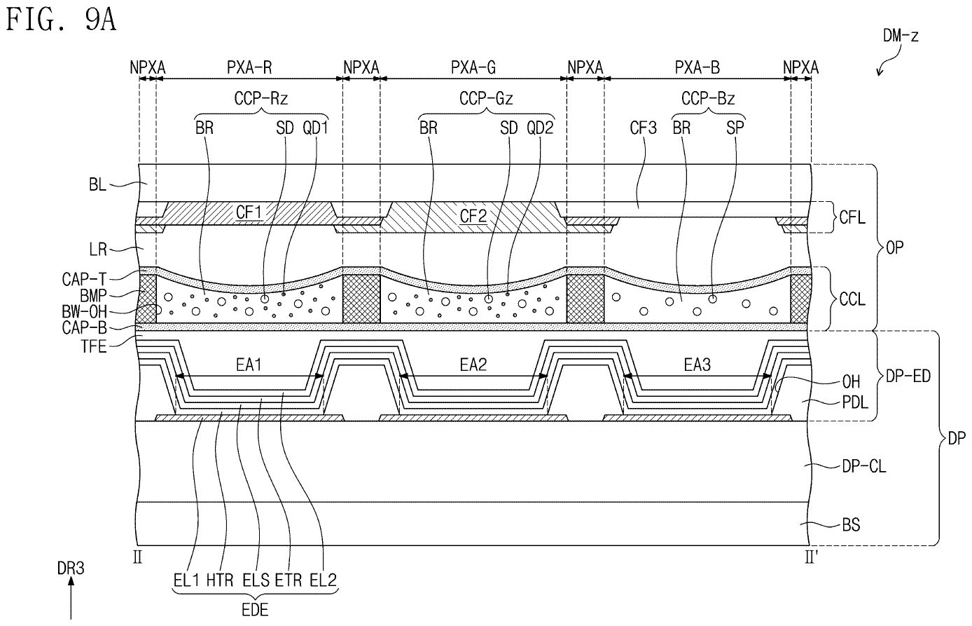

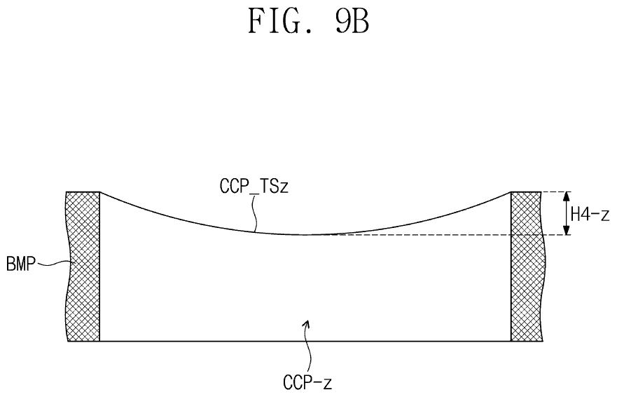

FIG. 9A is a cross-sectional view showing a portion of a display module according to Comparative Example. FIG. 9A is a view corresponding to FIG. 7. FIG. 9B is an enlarged cross-sectional view showing a portion of a light control layer according to Comparative Example. FIG. 9B is an enlarged view of a light control portion CCP-z among light control portions CCP-Rz, CCP-Gz, and CCP-Bz shown in FIG. 9A.

Comparative Example was manufactured as a display module DM-z having the structure of FIG. 9A. Referring to FIG. 9B, Comparative Example includes a light control portion CCP-z in which an upper surface CCP_TSz has a concave shape with respect to the third direction DR3. In Comparative Example, a height H4-z indicating a degree of concavity of the upper surface CCP_TSz of the light control portion CCP-z may be about 2 μm. The height H4-z shown in FIG. 9B may indicate a maximum separation distance in the third direction DR3 between a highest point having a maximum height and a lowest point having a minimum height from the upper surface of the display layer DP-ED (see FIG. 9A). Meanwhile, Example and Comparative Example were all manufactured as display modules having the same structure, except that the upper surface of the light control portion was convex/concave, respectively.

### (Evaluation of Display Modules)

The results of evaluating Example and Comparative Example are shown in Table 1 below. In the evaluation of the display modules in Table 1, front luminous efficiency for white light was measured. The improvement in the front luminous efficiency was indicated as a percentage (%) with Comparative Example set ac 100%

TABLE 1

| | Front luminous efficiency(%) |
|---|---|
| Comparative Example | 100 |
| Example | 175 |

Referring to the results in Table 1, it is determined that the display module of Example has improved front luminous efficiency compared to the display module of Comparative Example. The display module of Comparative Example includes a light control portion in which the upper surface has a concave shape compared to the module of Example, and accordingly, light emitted in an oblique direction with respect to the third direction (hereinafter, side light) is partially lost due to the division pattern, resulting in a decrease in luminance. That is, it is understood that the electronic device including the display module of Comparative Example may have relatively reduced luminance characteristics since the side light is partially not emitted to a display surface. Conversely, the display module of Example is found to have increased front luminous efficiency, including a light control portion formed by an expanding monomer and having the upper surface with a convex shape. It is understood that the electronic device including the display module of Example may have relatively increased front luminance characteristics.

The light control portion according to an aspect of this disclosure includes a base resin portion, and the base resin portion includes a polymer derived from a resin composition including a first monomer, i.e., an expanding monomer.

Accordingly, a display module according to an aspect of the disclosure may include a light control portion having a convex upper surface. The volume of the expanding monomer in the resin composition increases during polymerization, and thus the upper surface of the light control portion in an aspect may have a convex shape. The light control portion of an aspect has the upper surface with a convex shape, and thus the display module may exhibit high luminance characteristics, and an electronic device including the display module may exhibit excellent front luminance characteristics. That is, the display module according to an aspect and the electronic device including the same may exhibit excellent display quality.

A display module of an aspect and an electronic device including the same include a light control portion containing a polymer derived from an expanding monomer, and may thus exhibit excellent front luminance characteristics.

In the above, description has been made with reference to aspects, but those skilled or of ordinary skill in the art may understand that various modifications and changes may be made to the aspects insofar as such modifications and changes do not depart from the spirit and technical scope of the disclosure. Therefore, it should be understood that aspects described above are exemplary and are not to be limiting.

What is claimed is:

1. A display module comprising:
a display layer providing source light; and
a light control layer disposed on the display layer and including a plurality of light control portions, the plurality of light control portions are separated from one another,
wherein each of the plurality of light control portions includes a base resin portion,
the base resin portion includes a polymer derived from a resin composition containing a first monomer, and
the first monomer includes an expanding monomer.

2. The display module of claim 1, wherein the first monomer comprises a carbonate-based compound or a benzoxazine-based compound.

3. The display module of claim 1, wherein the first monomer comprises a compound represented by any one of Compound Group 1 below:

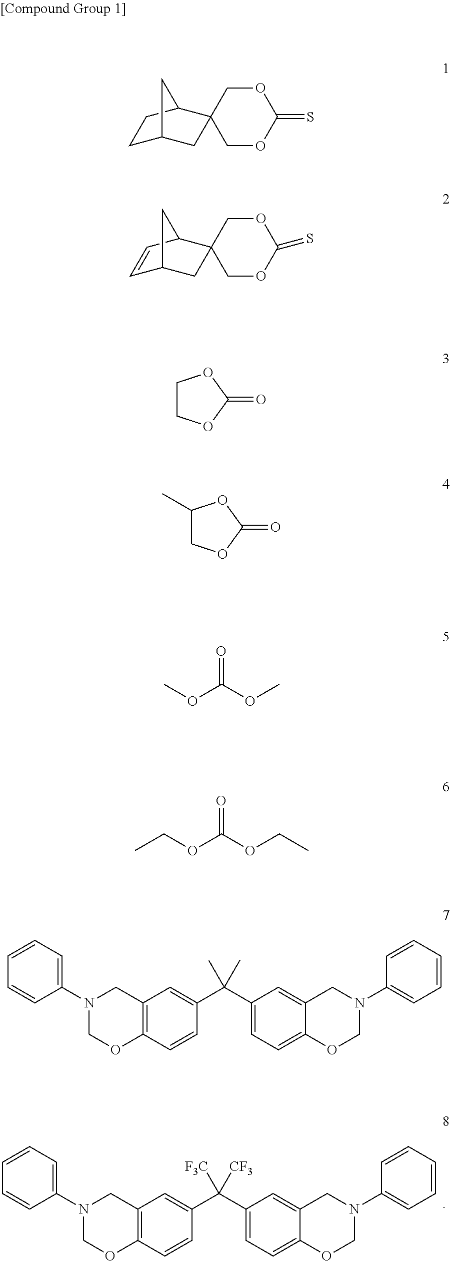

4. The display module of claim 1, wherein the resin composition comprises about 20 to about 70 percent by weight the first monomer.

5. The display module of claim 1, wherein the resin composition further comprises a second monomer different from the first monomer, and
the second monomer is hexamethylenediamine.

6. The display module of claim 5, wherein the resin composition comprises about 20 to about 70 percent by weight the first monomer and about 30 to about 80 percent by weight the second monomer.

7. The display module of claim 1, wherein at least some of the plurality of light control portions further comprises quantum dots dispersed in the base resin portion and converting a wavelength of the source light.

8. The display module of claim 1, wherein each of the plurality of light control portions further comprises scatterers dispersed in the base resin portion.

9. The display module of claim 8, wherein the scatterers comprise at least one of TiO₂, SiO₂, BaSO₄, BaO, ZnS, ZnO, Al₂O₃, CaCO₃, or hollow silica.

10. The display module of claim 1, wherein the light control layer further comprises a division pattern in which an opening exposing at least a portion of an upper surface of the display layer is defined, and
the plurality of light control portions are disposed in the opening and are separated from one another by the division pattern.

11. The display module of claim 10, wherein the upper surface of each of the plurality of light control portions has a convex shape in a direction away from the display layer.

12. The display module of claim 10, wherein a first height of the division pattern is less than a second height of one of the plurality of light control portions.

13. The display module of claim 10, wherein each of the plurality of light control portions comprises a flat portion disposed on the display layer, and a convex portion disposed on the flat portion.

14. The display module of claim 13, wherein a third height of the flat portion is less than a first height of the division pattern.

15. The display module of claim 13, wherein the convex portion has a fourth height of about 1 μm to about 3 μm.

16. The display module of claim 1, wherein the display module is separated into a first pixel region emitting red light, a second pixel region emitting green light, and a third pixel region emitting blue light, and
the plurality of light control portions comprises a first light control portion overlapping the first pixel region, a second light control portion overlapping the second pixel region, and a third light control portion overlapping the third pixel region.

17. The display module of claim 16, further comprising a color filter layer disposed on the light control layer,
wherein the color filter layer includes a first color filter overlapping the first pixel region and transmitting the red light, a second color filter overlapping the second pixel region and transmitting the green light, and a third color filter overlapping the third pixel region and transmitting the blue light.

18. The display module of claim 17, further comprising a low refractive layer disposed between the light control layer and the color filter layer.

19. A display module comprising:
a display layer providing source light; and
a light control layer disposed on the display layer,
wherein the light control layer includes:
a division pattern comprising openings exposing at least a portion of an upper surface of the display layer is defined; and
a plurality of light control portions disposed in the openings, the light control portions separated from one another by the division pattern,
at least some of the plurality of light control portions include quantum dots converting a wavelength of the source light,
each of the plurality of light control portions includes a flat portion disposed on the display layer, and a convex portion disposed on the flat portion, and
the convex portion has a height of about 1 μm to about 3 μm.

20. An electronic device capable of providing an image, comprising:
a window;
an outer case coupled to the window;
a display module disposed between the window and the outer case; and
wherein the display module includes:
a display layer providing source light; and
a light control layer disposed on the display layer and including a plurality of light control portions, which are separated from one another,
each of the plurality of light control portions includes a base resin portion,
the base resin portion includes a polymer derived from a resin composition containing a first monomer, and
the first monomer includes an expanding monomer.
